(19) United States
(12) Patent Application Publication
(10) Pub. No.: US 2019/0185984 A1
(43) Pub. Date: Jun. 20, 2019

(54) MASK STRIP, MASK, AND VAPOR-PLATING DEVICE

(71) Applicants: BOE Technology Group Co., Ltd., Beijing (CN); Ordos Yuansheng Optoelectronics Co., Ltd., Ordos, NM (US)

(72) Inventors: Chunchieh Huang, Beijing (CN); Shouhua Lv, Beijing (CN)

(21) Appl. No.: 16/054,076

(22) Filed: Aug. 3, 2018

(30) Foreign Application Priority Data
Dec. 18, 2017 (CN) 201721775254.6

(51) Int. Cl. C23C 14/04; H01L 51/00; H01L 51/56; C23C 14/12; C23C 14/22

(52) U.S. Cl. CPC C23C 14/042; H01L 51/0011; C23C 14/22; C23C 14/12; H01L 51/56

(57) ABSTRACT

The disclosure relates to the field of vapor-plating technologies, and discloses a mask strip, a mask, and a vapor-plating device to thereby improve the quality of vapor plating. The mask strip includes solder holes for soldering on a upper surface of a frame of a mask, and a first groove which is on the sides of the solder holes away from the upper surface of the frame, and communicates with the solder holes.

### CROSS-REFERENCE TO RELATED APPLICATION

This application claims priority of Chinese Patent Application No. 201721775254.6, filed on Dec. 18, 2017, which is hereby incorporated by reference in its entirety.

### FIELD

The present disclosure relates to the field of vapor-plating technologies, and particularly to a mask strip, a mask, and a vapor-plating device.

### BACKGROUND

The existing Organic Light-Emitting Diode (OLED) is typically fabricated using an organic vapor-plating film, where a Fine Metal Mask (FMM) is used as a mask, and an organic vapor-plating material is heated into vapor molecules, and then vapor-plated onto a backboard through openings of the mask.

### SUMMARY

Some embodiments of the disclosure provide a mask strip including solder holes for soldering on a upper surface of a frame of a mask, and a first groove; the first groove is on the sides of the solder holes away from the upper surface of the frame, and communicates with the solder holes.

Optionally, a quantity of solder holes for soldering on the upper surface of the frame of the mask is at least two.

Optionally, a protrusion is arranged on a side of the mask strip proximate to the upper surface of the frame, and the solder holes run through the protrusion.

Optionally, the first groove is a strip groove extending substantially perpendicular to a length direction of the mask strip, and/or the protrusion is a strip protrusion extending substantially perpendicular to a length direction of the mask strip.

Optionally, the first groove is a strip groove extending substantially perpendicular to a length direction of the mask strip, the protrusion is a strip protrusion extending substantially perpendicular to a length direction of the mask strip, and a size L1 of the protrusion in the length direction of the mask strip is equal to a size L3 of the first groove in the length direction of the mask strip.

Optionally, a depth H1 of the first groove satisfies: 5 μm<H1<10 μm.

Some embodiments of the disclosure further provide a mask including a frame, and at least one mask strip according to any one of the embodiments above of the disclosure, which is soldered and fixed on the upper surface of the frame.

Optionally, the angle between the inner side of the frame, and the upper surface of the frame is less than 90 degrees; the inner side of the frame faces a vapor-plating material vapored from a vapor-plating device.

Optionally, a protrusion is arranged on a side of the mask strip proximate to the upper surface of the frame, the solder holes run through the protrusion, and a second groove matching in shape with the protrusion is arranged on the upper surface of the frame.

Optionally, a height H2 of the protrusion is less than or equal to a height H3 of the second groove.

Optionally, the protrusion is a strip protrusion extending substantially perpendicular to the length direction of the mask strip, and the second groove is a strip groove extending substantially perpendicular to the length direction of the mask strip; and the size L1 of the protrusion in the length direction of the mask strip, and a size L2 of the second groove in the length direction of the mask strip satisfy: L1<L2.

Optionally, the size L1 of the protrusion in the length direction of the mask strip satisfies: 5 μm<L1<10 μm.

Some embodiments of the disclosure further provides a vapor-plating device including the mask according to any one of the embodiments above of the disclosure.

### BRIEF DESCRIPTION OF THE DRAWINGS

FIG. 1 is a schematic structural diagram of the mask in the vapor-plating chamber in the related art.

FIG. 2 is a schematic diagram of mask strips combined with a frame according to an embodiment of the disclosure.

FIG. 3 is a schematic diagram along the section A-A in FIG. 2.

FIG. 4 is a schematic structural diagram of a mask in a vapor-plating chamber according to an embodiment of the disclosure.

### DETAILED DESCRIPTION OF THE EMBODIMENTS

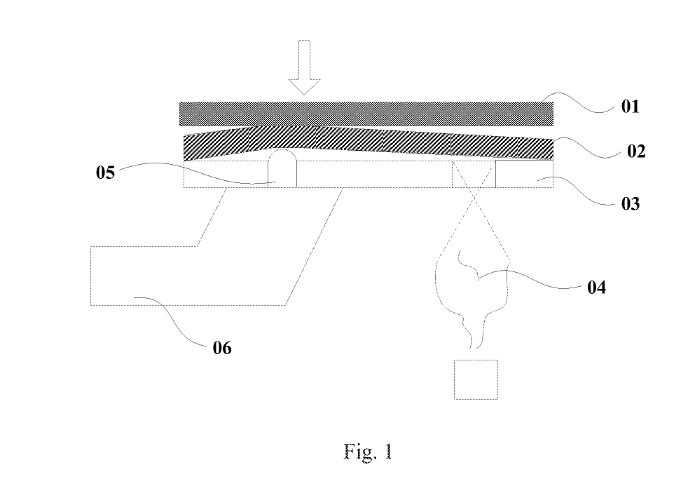

As illustrated in FIG. 1, the fine metal mask typically includes a metal frame 06, e.g., an invar frame, and metal mask strips 03 soldered on the metal frame 06, in the related art. In a vapor-plating process, the fine metal mask is placed in a vapor-plating chamber, and adhered on the lower surface of the backboard 02, and a cooling plate 01 is impressed on the upper surface of the backboard 02 to thereby cool the organic vapor-plating material 04 vapor-plated on the backboard 02.

Further referring to FIG. 1, a drawback in the related art lies in that each metal mask strip 03 is soldered on the metal frame 06 at a solder joint 5 above the upper surface of the fine metal mask, so that the backboard 02 adhered with the fine metal mask is bent at the solder joint 5, and thus colors of a pixel pattern vapor-plated onto the backboard 02 may be poorly mixed at the solder joint 5, thus degrading a good yield. Furthermore the backboard 02 tends to be bent at the solder joint 5, so when the cooling plate 01 is impressed on the upper surface of the backboard 02, the backboard 02 may be easily cracked at the solder joint 5 due to a stress, thus hindering normal production and lowering a production throughput.

In order to improve the quality of vapor plating so as to improve a good yield, embodiments of the disclosure provide a mask strip, a mask, and a plating device. In order to make the objects, technical solutions, and advantages of the disclosure more apparent, the disclosure will be described below in further details in connection with embodiments thereof.

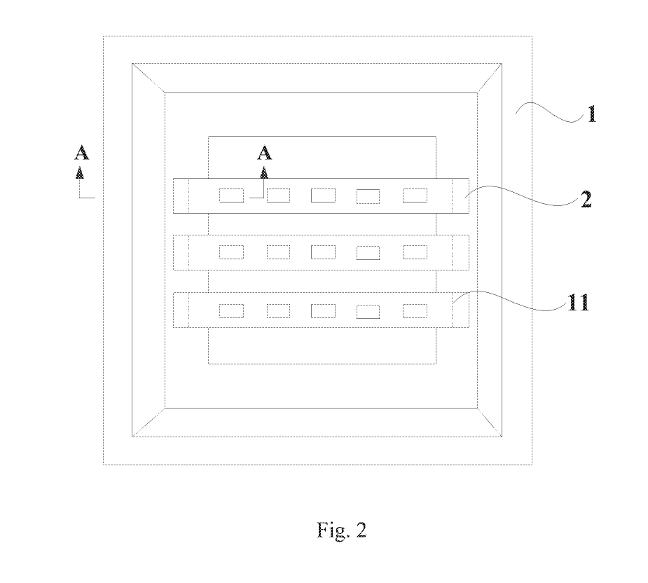

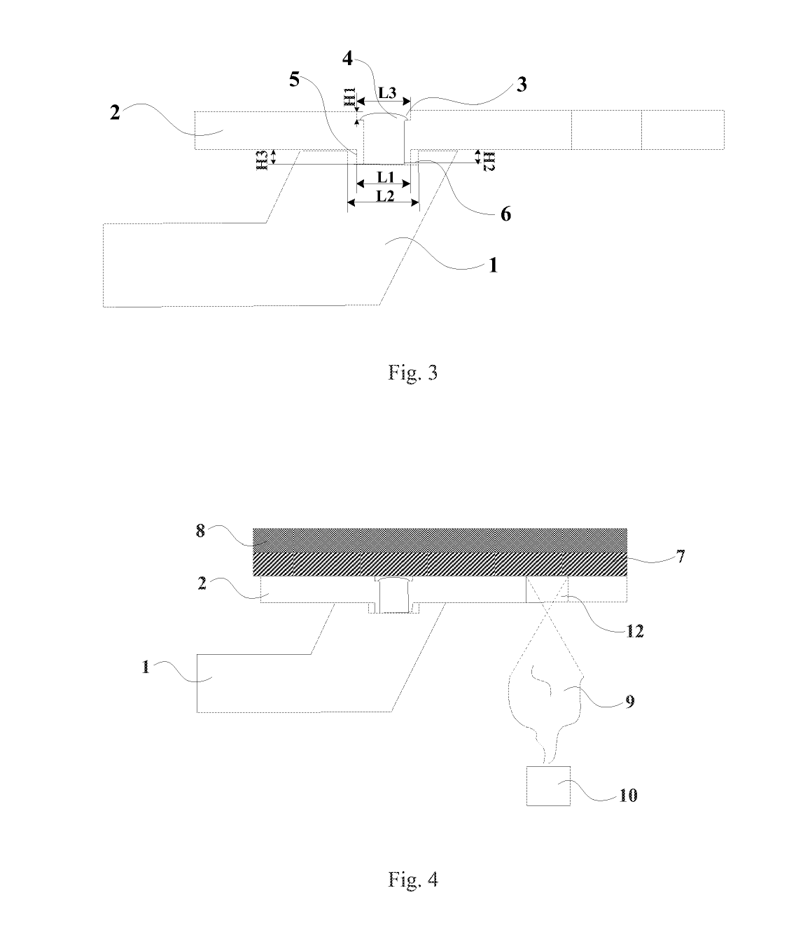

As illustrated in FIG. 2 and FIG. 3, some embodiments of the disclosure provide a mask strip 2 including solder holes 11 for soldering on a upper surface of a frame of a mask, and a first groove 3 which is on sides of the solder holes 11 away from the upper surface of the frame, and communicates with the solder holes 11.

In embodiments, the depth H1 of the first groove 3 will not be limited to any particular value as long as it satisfies 5 μm<H1<10 μm. When the first groove 3 satisfies this condition, a solder overflowing from the solder hole 11 can be well filled into the first groove 3 so that no solder joint will be above the upper surface of the mask strip 2.

In order to fabricate the mask using the mask strips 2 according to this technical solution, the mask strips 2 are soldered on the upper surface of the frame using the solder, and the solder overflowing from the solder holes 11 can be filled into the first grooves 3, so that the heights of the solder spots will not be above the upper surfaces of the mask strips. In order to vapor-plate the backboard using the mask according to this technical solution, the mask is placed in a vapor-plating chamber, and the surface, of the backboard, to be vapor-plated can be firmly adhered on the surfaces of the mask strips 2 on the sides thereof away from the frame to thereby improve the quality of vapor-plating pixels so as to improve a good yield.

As illustrated in FIG. 2 to FIG. 4, in an optional embodiment of the disclosure, the first groove 3 communicates with at least two solder holes 11. The number of the solder holes 11 communicating with the first groove 3 will not be limited to any particular number, but may be one, two or more, and when there are a plurality of solder holes 11, the mask strip 2 can be soldered on the frame 1 more firmly.

In an optional embodiment of the disclosure, there is a protrusion on the side of the mask strip proximate to the upper surface of the frame, and the solder holes run through the protrusion, so that a groove corresponding to the protrusion is also arranged on the frame on which the mask is fixed, to thereby enable the mask strip to be assembled with the frame more reliably.

The first groove and the protrusion will not be limited to any particular shapes, where the first groove can be a round groove, and/or the protrusion can be a round protrusion. When the first groove is a round groove, the round protrusion can have the same diameter as the round groove. When the round protrusion has the same diameter as the round groove, a fabrication process thereof can be simplified.

In an optional embodiment of the disclosure, the first groove is a strip groove extending substantially (±1°) perpendicular to the length direction of the mask strip, and/or the protrusion is a strip protrusion extending substantially (±1°) perpendicular to the length direction of the mask strip. When the groove is arranged as a strip groove, and the protrusion is arranged as a strip protrusion, a fabrication process thereof can be simplified.

As illustrated in FIG. 3, in an optional embodiment of the disclosure, the first groove 3 is a strip groove extending substantially (±1°) perpendicular to the length direction of the mask strip 2, the protrusion 5 is a strip protrusion extending substantially (±1°) perpendicular to the length direction of the mask strip 2, and the size L1 of the protrusion 5 in the length direction of the mask strip 2 is equal to the size L3 of the first groove 3 in the length direction of the mask strip 2. Their sizes are thus arranged to thereby make it easier to control a process of forming the protrusion 5 and the first groove 3 through etching.

As illustrated in FIG. 2 and FIG. 3, some embodiments of the disclosure further provide a mask including a frame 1, and at least one mask strip 2 soldered and fixed on the upper surface of the frame 1, where the mask strip 2 includes solder holes 11 leading to the upper surface of the frame 1, and a first groove 3 which is on the sides of the solder holes 11 away from the upper surface of the frame 1, and communicating with the solder holes 11.

In order to fabricate the mask according to this technical solution, the mask strip 2 is soldered on the upper surface of the frame 1 using a solder, and the solder overflowing from the solder holes 11 can be filled into the first groove 3, so that the height of the solder joint 4 will not be above the upper surface of the mask strip 2. As illustrated in FIG. 4, in order to vapor-plate the backboard 7, the mask is placed in a vapor-plating chamber, and a vapor-plating material 9 is heated, vapored from a crucible 10, and vapor-plated onto a backboard 7 adhered with the mask strip 2 through a valid vapor-plating opening 12 of the mask strip 2, thus resulting in a pixel pattern. With the mask according to this technical solution, the surface, of the backboard 7, to be vapor-plated can be firmly adhered on the surface of the mask strip 2 on the side thereof away from the frame 1 to thereby improve the quality of vapor-plating the pixel so as to improve a good yield. Furthermore when a cooling plate 8 cooling the vapor-plating material 9 vapor-plated onto the backboard 7 is impressed on the upper surface of the backboard 7, the backboard 7 can be avoided in effect from being cracked at the solder joint due to a stress, to thereby improve the good yield.

As illustrated in FIG. 3 and FIG. 4, in an optional embodiment of the disclosure, the inner side of the frame 1 refers to the surface of the frame 1 on the side thereof facing the vapor-plating material vapored from the vapor-plating device, so the angle between the inner side of the frame 1, and the upper surface of the frame 1 is less than 90 degrees, so that the vapor-plating material in the vapor state can be better collected onto the surface, of the backboard 7, to be vapor-plated.

Further referring to FIG. 3 and FIG. 4, in another optional embodiment of the disclosure, there is a protrusion 5 on the side of the mask strip 2 proximate to the upper surface of the frame 1, the solder holes run through the protrusion 5, and a second groove 6 matching in shape with the protrusion 5 is arranged on the upper surface of the frame 1. The protrusion 5 and the groove 6 are arranged respectively on the mask strip 2 and the frame 1, so that the mask strip 2 can be assembled with the frame 1 more reliably before the mask strip 2 is soldered on the frame 1.

As illustrated in FIG. 3, in respective embodiments of the disclosure, the height H2 of the protrusion 5 is less than or equal to the depth H3 of the second groove 6. When the height of the protrusion 5 is less than or equal to the depth of the second groove 6, the protrusion 5 can be completely accommodated in the second groove 6, so that the mask strip 2 can be adhered on the frame 1 more firmly, and thus the mask 2 can be soldered on the frame 1 more reliably.

As illustrated in FIG. 3 and FIG. 4, in an optional embodiment of the disclosure, there is a protrusion 5 on the side of the mask strip 2 proximate to the upper surface of the frame 1, and the solder holes run through the protrusion 5; a second groove 6 matching in shape with the protrusion 5 is arranged on the upper surface of the frame 1; the protrusion 5 is a strip protrusion extending substantially (±1°) perpendicular to the length direction of the mask strip 2, and the second groove 6 is a strip groove extending substantially (±1°) perpendicular to the length direction of the mask strip 2; the size L1 of the protrusion 5 in the length direction of the mask strip 2, and the size L2 of the second groove 6 in the length direction of the mask strip 2 satisfy: L1<L2. When both the second groove 6 and the protrusion 5 are structured as strips, a fabrication process thereof can be simplified in effect; and the size of the second protrusion 6 is greater than the size of the protrusion 5 in the length direction of the mask strip 2, so that the protrusion 5 can be placed in the second groove 6 more easily, and while the mask strip 2 is being soldered on the frame 1, the second groove 6 can also accommodate a part of the excessive solder, so that the solder joint 4 will not be above the upper surface of the mask strip 2.

In respective embodiments of the disclosure, when the protrusion 5 is a strip protrusion extending substantially (±1°) perpendicular to the length direction of the mask strip 2, the size L1 of the protrusion 5 in the length direction of the mask strip 2 will not be limited to any particular value as long as it satisfies 5 μm<L1<10 μm. When the size L1 of the protrusion 5 satisfies this condition, a sufficient space can be reserved for the solder holes to accommodate a sufficient solder to thereby make the mask strip 2 soldered on the frame 1 more reliably.

Some embodiments of the disclosure further provide a vapor-plating device including the mask according to any one of the embodiments above of the disclosure.

In order to vapor-plate the backboard using the vapor-plating device according to this technical solution, the mask strip of the mask is soldered on the upper surface of the frame using the solder, and the solder overflowing the solder holes can be filled into the first groove, so that the height of the solder spot will not be above the upper surface of the mask strip, and thus the surface, of the backboard, to be vapor-plated can be firmly adhered on the surface of the mask on the side thereof away from the frame to thereby improve the quality of vapor-plating the pixel so as to improve a good yield.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. A mask strip, comprising solder holes for soldering on a upper surface of a frame of a mask, and a first groove; the first groove is on sides of the solder holes away from the upper surface of the frame, and communicates with the solder holes.

2. The mask strip according to claim 1, wherein a quantity of the solder holes for soldering on the upper surface of the frame of the mask is at least two.

3. The mask strip according to claim 1, wherein a protrusion is arranged on a side of the mask strip proximate to the upper surface of the frame, and the solder holes run through the protrusion.

4. The mask strip according to claim 3, wherein the first groove is a strip groove extending substantially perpendicular to a length direction of the mask strip, and/or the protrusion is a strip protrusion extending substantially perpendicular to a length direction of the mask strip.

5. The mask strip according to claim 3, wherein a size L1 of the protrusion in a length direction of the mask strip, and a size L3 of the first groove in the length direction of the mask strip satisfy: L1<L3.

6. The mask strip according to claim 1, wherein a depth H1 of the first groove satisfies: 5 μm<H1<10 μm.

7. A mask, comprising a frame, and at least one mask strip according to claim 1, the at least one mask strip is soldered and fixed on the upper surface of the frame.

8. The mask according to claim 7, wherein an angle between an inner side of the frame and the upper surface of the frame is less than 90 degrees; the inner side of the frame faces a vapor-plating material vapored from a vapor-plating device.

9. The mask according to claim 7, wherein a protrusion is arranged on a side of the mask strip proximate to the upper surface of the frame, the solder holes run through the protrusion, and a second groove matching in shape with the protrusion is arranged on the upper surface of the frame.

10. The mask according to claim 9, wherein a height H2 of the protrusion is less than or equal to a height H3 of the second groove.

11. The mask according to claim 9, wherein the protrusion is a strip protrusion extending substantially perpendicular to a length direction of the mask strip, and the second groove is a strip groove extending substantially perpendicular to a length direction of the mask strip; and a size L1 of the protrusion in the length direction of the mask strip, and a size L2 of the second groove in the length direction of the mask strip satisfy: L1<L2.

12. The mask according to claim 11, wherein the size L1 of the protrusion in the length direction of the mask strip satisfies: 5 μm<L1<10 μm.

13. A vapor-plating device, comprising the mask according to claim 7.
